(19) United States
(12) Patent Application Publication
(10) Pub. No.: US 2009/0218688 A1
(43) Pub. Date: Sep. 3, 2009

(54) OPTIMIZED PASSIVATION SLOPE FOR SOLDER CONNECTIONS

(75) Inventors: Stephen P. Ayotte, Bristol, VT (US); Timothy H. Daubenspeck, Colchester, VT (US); Jeffrey Gambino, Westford, VT (US); Christopher D. Muzzy, Burlington, VT (US); David L. Questad, Hopewell Junction, NY (US); Wolfgang Sauter, Richmond, VT (US)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignee: INTERNATIONAL BUSINESS MACHINES CORPORATION, ARMONK, NY (US)

(21) Appl. No.: 12/039,134

(22) Filed: Feb. 28, 2008

(51) Int. Cl. H01L 23/52

(52) U.S. Cl. 257/738; 257/E23.021

(57) ABSTRACT

A semiconductor structure includes at least one bond pad. An insulator layer is on the surface of the semiconductor chip and on a portion of the bond pad. The polyimide layer comprises a bottom surface contacting and coplanar with the surface of the semiconductor chip, a top surface opposite and parallel to the bottom surface of the polyimide layer, and a sloped side between corresponding ends of the top surface of the polyimide layer and the bottom surface of the polyimide layer. The sloped side joins the bottom surface of the polyimide layer at the top surface of the bond pad. The sloped side of the polyimide layer forms an angle less than 50° with the bottom surface of the polyimide layer.

### BACKGROUND

### Field of the Invention

The embodiments of the invention generally relate to solder ball connections and more particularly to a structure that includes a more gently sloped insulator layer above the bond pad.

Chip BEOL (back-end-of-line) delaminations underneath solder balls (used to connect integrated circuit semiconductor chips to carriers, substrates, and packaging) are sometimes caused by the reflow process. Such defects increase with the use of with lead-free solder balls and organic laminates. The thermal mismatch between the laminate and the chip causes the solder balls to be under stress when the chip and laminate cool down from above reflow temperatures. Lead-free solder is significantly stiffer than a leaded solder, which can damage structures to which the solder is firmly attached.

### SUMMARY

Embodiments herein provide a semiconductor structure (such as, for example, a semiconductor chip) that includes at least one bond pad. The surface of the semiconductor chip is coplanar with the top surface of the bond pad. An insulator layer (such as a polyimide layer) is on the surface of the semiconductor chip and on a portion of the bond pad.

One feature of embodiments herein is that the polyimide layer comprises a sloped side between corresponding ends of the top surface of the polyimide layer and the bottom surface of the polyimide layer. The sloped side joins the bottom surface of the polyimide layer at the top surface of the bond pad. The sloped side of the polyimide layer forms an angle less than 50° with the bottom surface of the polyimide layer.

A metallization layer, such as a ball limiting metallurgy (BLM) layer, is on the polyimide layer and the bond pad. The BLM layer comprises top and bottom surfaces that match the shape of the polyimide layer. Therefore, the BLM layer also has a sloped side that forms an angle less than 50° with the surface of the semiconductor structure/bond pad. Therefore, the benefits of the sloped side of the insulator layer are transferred to the BLM layer which allows the solder ball that is on the BLM layer and positioned above the bond pad to have more latitude when experiencing stresses that run parallel to the surface of the semiconductor structure.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic diagram of an integrated circuit structure;

FIG. 2 is a schematic diagram of an integrated circuit structure; and

FIG. 3 is a schematic diagram of an integrated circuit structure.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, damage, such as delamination can be caused by excessive tensile force applied to a lead-free solder ball on a semiconductor chip. Polyimide is commonly the final passivation layer on the chip surface. Polyimide is a relatively soft an organic material that can be used to absorb the stress exerted from the solder on the brittle chip. Conventionally, the sidewall slope is a result of the process limitations. However, with embodiments herein the sidewall slope of the polyimide is specifically engineered to be optimized so as to significantly reduce peak stresses.

U.S. Patent Publication 2006/0076677 (the complete disclosure of which is incorporated herein by reference) explains many of the details regarding the processes and materials used to form a bond pad, ball limiting metallurgy (BLM), the solder balls and other similar structures. The teachings from U.S. Patent Publication 2006/0076677 are not repeated herein and the reader is referred to the reference for the details regarding such teachings.

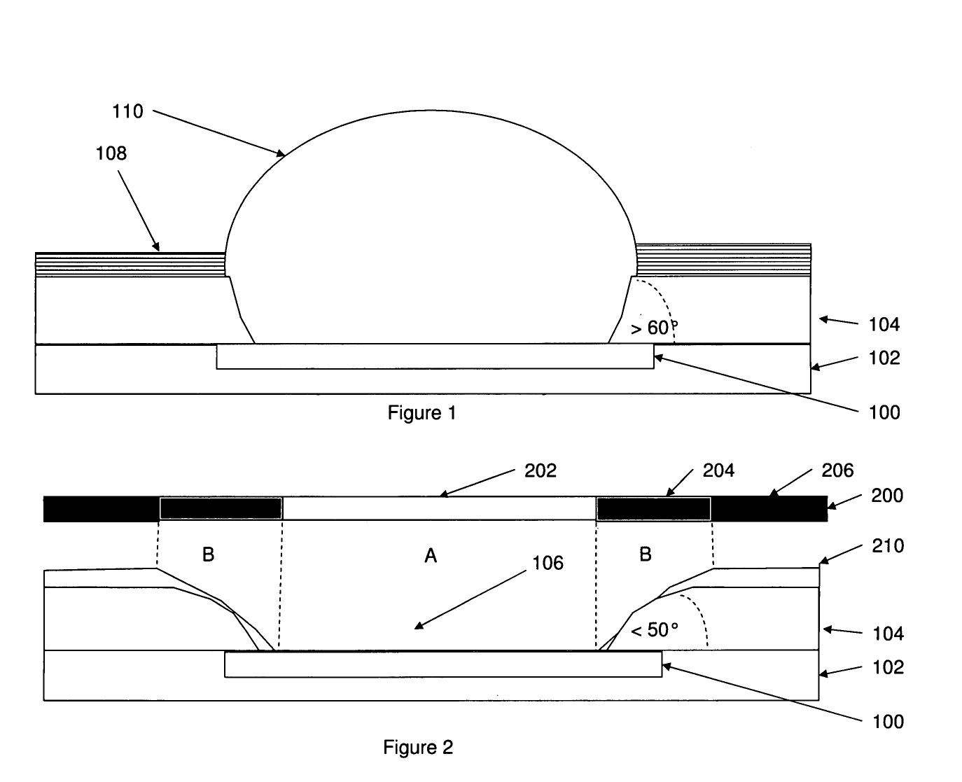

As shown in FIG. 1, a semiconductor device (chip) comprises a wafer or substrate 102 and a bonding pad 100. The substrate 102 may comprise silicon, gallenium arsenide or other known semiconducting materials and the bonding pad 100 may be formed from copper, aluminum, or similar metallic compounds. The chip further comprises a passivation layer 104 formed of an insulator, such as the previously mentioned polyimide or silicon dioxide that is layered over the substrate 102. Other insulator materials that can be used include an insulating polymer, oxide, nitride (SiN, SiON), silicon nitride, or carbide dielectrics (SiC, SiCN, SiCO, etc.). The passivation layer 104 includes at least one terminal via 106 that exposes the bonding pad 100.

Ball limiting metallurgy (BLM) 108 is positioned over the passivation layer 104 and in the via 110. The BLM structure 108 comprises multiple layers of metals and/or metal compounds sequentially deposited by evaporation over the passivation layer 104 and via 110. See U.S. Patent Publication 2008/0008900 (the complete disclosure of which is incorporated herein by reference) for a complete discussion of BLM structures. A solder ball 110 is formed over the BLM layer.

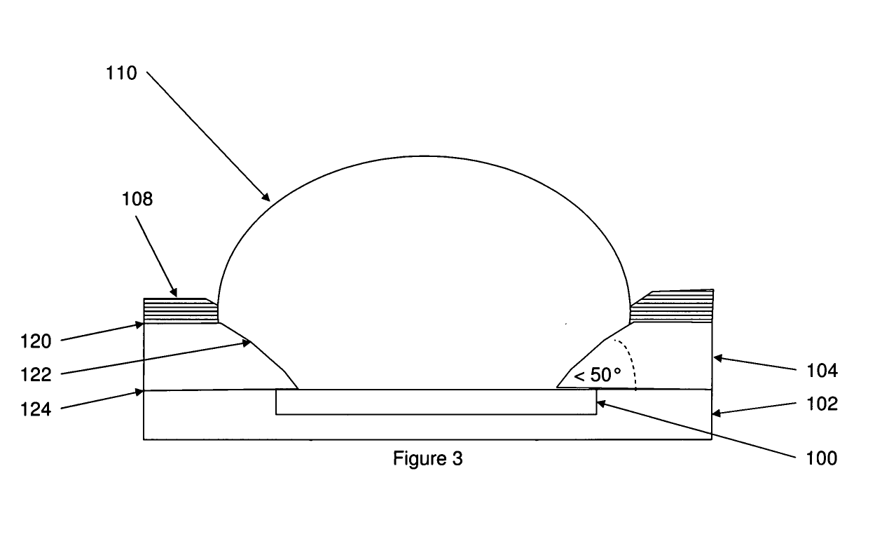

As mentioned above, the sidewall slope in conventional structures is a result of the process limitations. Typically, the sidewall slope measured as an angle between the plane of the bond pad 100 (the same plane forming the surface of the semiconductor 102 and the bottom of the insulator layer 104) is greater than 60°. Embodiments herein, shown in FIGS. 2 and 3 provide a different structure that helps to compensate for the increased stresses in the chip that are caused by the use of lead-free solders and materials such as organic laminated carriers and substrates.

More specifically, as shown in FIG. 3, embodiments herein provide a semiconductor structure 102 (such as, for example, a semiconductor chip) that includes at least one bond pad 100. The surface of the semiconductor chip 102 is coplanar with the top surface of the bond pad 100. An insulator layer 104 (such as a polyimide layer) is on the surface of the semiconductor chip 102 and on a portion of the bond pad 100.

One feature of embodiments herein is that the polyimide layer 104 comprises a bottom surface 124 contacting and coplanar with the surface of the semiconductor chip 102, a top surface 120 opposite and parallel to the bottom surface of the polyimide layer 104, and a sloped side 122 between corresponding ends of the top surface 120 of the polyimide layer 104 and the bottom surface 124 of the polyimide layer 104. The sloped side 122 joins the bottom surface 124 of the polyimide layer 104 at the top surface of the bond pad 100. The sloped side 122 of the polyimide layer 104 forms an angle less than 50° with the bottom surface of the polyimide layer 104. For example, the angle can be between 30° and 50°, and can be 45°.

A metallization layer 108, such as a ball limiting metallurgy (BLM) layer, is on the polyimide layer 104 and the bond pad 100. The BLM layer 108 comprises top and bottom surfaces that match a shape of the polyimide layer 104. Therefore, the BLM layer 108 also has a sloped side that forms an angle less than 50° with the surface of the semiconductor structure/bond pad 100. Therefore, the benefits of the sloped side of the insulator layer are transferred to the BLM layer which allows the solder ball 110 (that is on the BLM layer 108 and positioned above the bond pad 100) to have more latitude when experiencing stresses that run parallel to the surface of the semiconductor structure.

In other words, the more gentle slope of the sidewall 122 of the insulator layer 104 and a matching slope of the BLM layer 108 of embodiments herein provide less lateral resistance (in the direction parallel to the top of the semiconductor chip 104) which allows the solder ball 110 to deform more easily without causing structural defects within the solder ball 110, or associated delaminations within structures that are connected to the solder ball 110.

FIG. 2 illustrates a number of methods by which the sidewalls of the insulator layer 104 can be formed with a more gradual slope. More specifically, FIG. 2 illustrates a gray tone mask 200 that includes some transparent sections 202, some non-transparent sections 206 and some semi-transparent (gray) sections 204.

The non-transparent sections 206 do not allow light to pass; the semi-transparent sections 204 allow some light to pass (labeled as region B in FIG. 2); and the transparent sections 202 allow all transmitted light to pass (labeled as region A in FIG. 2). The semi-transparent sections 204 can further have a gradual transition of transparency so as to allow less light to pass in the regions closer to the non-transparent regions 206 and more light to pass in the regions closer to the transparent region 202.

When such a mask 200 is utilized to expose a photosensitive polyimide 104, the regions closest to the full exposure region (region A) will receive a greater amount of light and will be exposed more than regions that are closer to the non-transparent sections 206. This gradual change of exposure levels and subsequent development causes more of the photosensitive polyimide to be removed closer to the bond pad and less of the photosensitive polyimide to be removed from areas that are further away from the bond pad 100. Thus, by controlling the nature of the semi-transparent sections 204 of the mask 200, the slope of the sidewall of the photosensitive polyimide 104 can be precisely controlled to achieve whatever slope angle is desired.

Alternatively, an additional polyimide layer 210 can be utilized to alter the slope of the polyimide layer 104. The additional polyimide layer 210 can have different characteristics than the polyimide layer 104. For example, the additional polyimide layer 210 can be of an opposite polarity, can be non-photosensitive, etc. For example, the additional polyimide layer 210 can be formed and can be developed with easily controlled development materials such as dilute tetramethylammonium hydroxide (TMAH). Then, a material removal process (such as blanket O₂ Ash or RIE) could be performed, followed by a final curing process. This would reduce the slope to the desired angle.

Therefore, as shown above, the more gentle slope of the sidewall 122 of the insulator layer 104 (and matching slope of the BLM layer 108) of embodiments herein provide less lateral resistance (in the direction parallel to the top of the semiconductor chip 104) which allows the stiffer lead-free solder ball 110 to deform more easily without causing structural defects within the solder ball 110, or associated structures that are connected to the solder ball 110. This reduces defects and increases reliability and yield.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. A semiconductor structure comprising:
a surface having at least one bond pad, wherein said surface of said semiconductor structure is coplanar with a top surface of said bond pad;
an insulator layer on said surface of said semiconductor structure and on a portion of said bond pad, wherein said insulator layer comprises:
a bottom surface contacting and coplanar with said surface of said semiconductor structure;
a top surface opposite and parallel to said bottom surface of said insulator layer; and
a sloped side between corresponding ends of said top surface of said insulator layer and said bottom surface of said insulator layer, wherein said sloped side joins said bottom surface of said insulator layer at said top surface of said bond pad, and wherein said sloped side of said insulator layer forms an angle less than 50° with said bottom surface of said insulator layer;
a metallization layer on said insulator layer and said bond pad, wherein said metallization layer comprises top and bottom surfaces that approximately match a shape of said insulator layer; and
a solder ball on said metallization layer and positioned above said bond pad.

2. The structure according to claim 1, all the limitations of which are incorporated herein by reference, wherein said solder ball comprises a lead-free solder.

3. The structure according to claim 1, all the limitations of which are incorporated herein by reference, wherein said metallization layer comprises a laminated structure.

4. A semiconductor chip comprising:
a surface having at least one bond pad, wherein said surface of said semiconductor chip is coplanar with a top surface of said bond pad;
a polyimide layer on said surface of said semiconductor chip and on a portion of said bond pad, wherein said polyimide layer comprises:
a bottom surface contacting and coplanar with said surface of said semiconductor chip;
a top surface opposite and parallel to said bottom surface of said polyimide layer; and
a sloped side between corresponding ends of said top surface of said polyimide layer and said bottom surface of said polyimide layer, wherein said sloped side joins said bottom surface of said polyimide layer at said top surface of said bond pad, and wherein said sloped side of said polyimide layer forms an angle less than 50° with said bottom surface of said polyimide layer;
a ball limiting metallurgy (BLM) layer on said polyimide layer and said bond pad, wherein said BLM layer comprises top and bottom surfaces that approximately match a shape of said polyimide layer; and
a solder ball on said BLM layer and positioned above said bond pad.

5. The semiconductor chip according to claim 4, all the limitations of which are incorporated herein by reference, wherein said solder ball comprises a lead-free solder.

6. The semiconductor chip according to claim 4, all the limitations of which are incorporated herein by reference, wherein said BLM layer comprises a laminated structure.
